(19) United States
(12) Patent Application Publication
(10) Pub. No.: US 2005/0098843 A1
(43) Pub. Date: May 12, 2005

(54) Addressable active materials and technology applications

(76) Inventor: Igor Touzov, Cary, NC (US)

Correspondence Address: IGOR V TOUZOV, 311 CASTLE HAYNE DRIVE, CARY, NC, 27519, US

(21) Appl. No.: 10/707,242

(22) Filed: Nov. 30, 2003

Related U.S. Application Data
(63) Continuation of application No. 60/319,744, filed on Dec. 1, 2002.

(51) Int. Cl. H01L 31/0232

(52) U.S. Cl. 257/432

(57) ABSTRACT

A new type of continuously addressable active material forming linear fibers, woven fabric, or flexible sheets is capable of random read/write access to any location within continuous one-dimensional or two-dimensional range. These materials provide high up to 10 nm spatial resolution of addressing and nanosecond scale access time. They provide new approach for efficient and inexpensive integration of ultra large planar and linear arrays of microstructures.

### CROSS REFERENCE TO RELATED APPLICATIONS

This application is a regular application of provisional Patent Application No. 60/319,744, filed Dec. 1, 2002 which is hereby incorporated by reference in its entirety for all purposes

### BACKGROUND OF INVENTION

1. Field of the Invention

The present invention relates generally to smart materials. More particularly, the present invention relates to continuous and segmented transducers with very high geometrical aspect ratios. In some specific cases, the present invention relates to real-time display systems, active apparel, and distributed high-density sensors.

2. Background of the Invention

Advances of micro- and nano-technology dramatically extend present view of engineering and scientific community on definition of word material. It is now includes not only naturally or chemically produced substances but also comprises complex micro-technologically engineered structures that possess advanced properties. Some examples of such advanced materials include family of optical polymer films (filters, polarizer, electro-chromic, etc.), high strength composites, photonic crystals, holographic films.

Information technology uses another type of macroscopic micro-devices such as plasma displays and other pixilated information panels that formally do not fit in definition of advanced materials. Because, all such devices represent arrays of micro-elements with individual means of addressing. Another type of devices such as described in U.S. Pat. No. 6,399,939 represent array of discrete sensors that individually accessed.

The growth of such arrays and increase in their geometrical density causes an increase in complexity of addressing protocols and circuits. Average modern computer screen has 1024+786 address connectors that tend to grow proportionally with display resolution.

Contrary old fashion analog CRT displays has much simpler design that requires only single input connector to modulate e-beam. Still such devices are unable to compete with digital flat panel displays due to weight, power and size limitations.

The present invention provides new technology that creates a new class of advanced materials that possess property of real-time addressability of almost any geometrical location, and still remain classified as a material and not an array or an aggregate of elements. This class of advanced materials allows very large aspect rations and could be realized as a fiber or a film, as well as a bulk part.

### SUMMARY OF INVENTION

The present invention utilizes phenomena of wave interference in nonlinear media. Particularly, one of preferred embodiments employs interference of acoustic waves. Yet another preferred embodiment employs interference of RF electromagnetic waves, and yet another preferred embodiment uses interference of light in IR-UV wavelength range. In each particular implementation of disclosed embodiments it is critical to use specific mode and polarization of interfering waves, nevertheless in majority of cases similar functionalities can be achieved using waves of alternative modes and polarizations. That is why it will be assumed, unless specially noted, that each embodiment can employ any applicable wave mode or polarization.

Advanced materials disclosed in the present invention utilize interference in cases of lateral, planar, and volume wave propagations. These materials allow fast targeting of selected location and focused delivery of particular type of energy there. Selected embodiments illustrate such delivery of thermal, electric, mechanical, or optical power.

The present invention further demonstrates uses of these materials in various applications. Some examples show integration of these addressable materials with arrays of discrete devices. Other examples show join use of addressable materials with other types of modern advanced materials, which allows construction of new specialized advanced materials for targeted applications.

Merge of functional materials with addressable material creates functional and logical terminology of functional and address layers. These layers refer to logical separation in functions performed by various components composing the material. The address layer structure in some cases virtually fused in structure of functional layer. The term layer itself in such cases does not stand for planar structure, and equally applicable to fibers and bulk structures. Although address layer disclosed in the present invention is always continuous advanced material, the functional layer sometimes violates definition of material and can be formed by collection of discrete components. It will become obvious to one skilled in the art that it is virtually impossible to describe all variety of applications and fictionalizations the addressable materials of the present invention can participate in. That is why terms of functional logical layer or in some cases functional material are employed throughout the document. In all such cases, except when it is specially noted, it is assumed that similar functional elements can be implemented as a single continuous structure or be segmented on smaller fractions.

One of the selected embodiments demonstrates the use of advanced material having shape of a fiber. These fibers then employed to construct woven fabric. Such fabric preserves advanced properties of initial material while providing variable shape.

Some of selected embodiments disclose construction of addressable materials with elastic properties.

### BRIEF DESCRIPTION OF DRAWINGS

FIG. 1 is conceptual diagram of the principal employed by address layer is shown on FIG. 1. Design utilizes two waveguides 101 and 102 each capable of transmitting energy pulse at least in one direction.

FIG. 2 is conceptual diagram shown on FIG. 2 illustrates principle utilized in single waveguide design of address layer. Interference of two pulses occurs in the same media as their propagation.

FIG. 3 shows phase inversion of first pulse with respect to the second pulse.

FIG. 4 shows interference of two pulses that propagate in the same direction along address layer.

FIG. 5 shows address layer waveguide utilizing interference of two pulses with different polarizations.

FIG. 6 shows basic technological steps required to produce single fiber that can receive address signal at any location along its path.

FIG. 7 shows use of spiral substrate to produce flexible fibers.

FIG. 8 is addressable fiber utilizing tunnel effect.

FIG. 9 shows interference of monochromatic light pulses propagating in Kerr media.

FIG. 10 is optical address layer utilizing Kerr media.

FIG. 11 is acoustic address layer.

FIG. 12 shows hybrid address layer.

FIG. 13 is hybrid address layer with ordered patterns.

FIG. 14 is layout of address fiber in ordered woven fabric pattern.

FIG. 15 is pattern type allowing simultaneous addressing of multiple surface areas of the address layer.

FIG. 16 is tree wave interference in address layer.

FIG. 17 is address layer with parallel front interference.

FIG. 18 is address layer with triple front collision interference.

FIG. 19 is acoustic-mechanical address transducer layer.

FIG. 20 is layout of mechanical pin transducer in address layer.

FIG. 21 is poling process of planar functional layer.

FIG. 22 is a diagram of operation of electro-optical functional layer.

FIG. 23 is pulse interference in nonlinear mixed address layer.

FIG. 24 is address transducer layer with FET structure.

FIG. 25 is resistive functional layer.

FIG. 26 is thermally active addressable fiber.

FIG. 27 is control diagram for thermally active addressable fiber.

FIG. 28 is 2D thermally active addressable film.

FIG. 29 is control diagram for 2D thermally active addressable film.

FIG. 30 is example application of thermally active addressable fiber.

FIG. 31 is aggregation of multiple thermally active addressable fibers.

FIG. 32 is hybrid thermally active addressable film.

FIG. 33 is single and multi-face layout of two-dimensional addressable active material.

FIG. 34 is example applications of thermally active addressable fibers.

FIG. 35 is control diagram for thermally active addressable film with heat flux sensor layer.

FIG. 36-41 shows sample designs of reactor cells.

FIG. 42 is example layout of reactor cells.

FIG. 43 laminated structure of discrete functional layer.

FIG. 44 is aggregated addressing schema for discrete functional layer.

### DETAILED DESCRIPTION

Addressable Active Material has logical layer structure that is used through the description. These layers are: address layer, and functional layer. Address layer in addition to address waveguide layer may include any of the following: data layer, address transducer layer, data transducer layer. Functional layer additionally may include sensor and control logical layers. Each layer in this model except address waveguide layer is optional. Logical layer model allows variety of possible combinations.

Address waveguide layer is responsible for propagation of addressing signal trough the material. Address transducer layer is responsible for receiving addressing signal and directing it to the functional layer. Data transducer layer is responsible for encoding sensor data and posting them to data layer. Data layer is responsible for propagation of encoded data through the material. Sensor layer is responsible for generating signal representing some physical characteristics and in some embodiments also providing this signal to control layer or data transducer layer. Control layer is responsible for conversion of signals received from other layers into physical responses.

Continuously Addressable Fiber

One-dimensional continuously addressable material employs address waveguide layer that confines wave propagation to single path curve. The concept and possible implementations of continuous (non-discrete) addressing will be described in more details here.

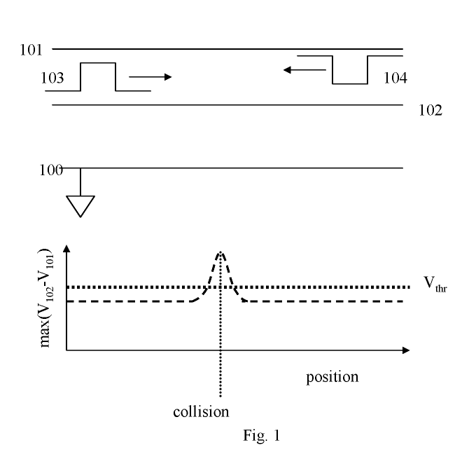

Conceptual diagram of the principal employed by address layer is shown on FIG. 1. Design utilizes two waveguides 101 and 102 each capable of transmitting energy pulse at least in one direction. The term energy pulse stands for temporal distortion in stationary energy state of a system. This distortion may have a form of intensity, frequency, phase, mode, or polarization changes.

In simple example shown on FIG. 1 said energy pulse has a form of nearly rectangular voltage pulse propagating through electrical transmission line. Dielectric media of each waveguide selected to have low frequency dispersion and low electrical loss for electric field intensities below certain threshold. Media between waveguides has similar properties and may have lower threshold. These thresholds are virtual, since most nonlinear media or devices have no clear separation between their linear and nonlinear zones.

For purpose of this simplistic example it is assumed that amplitudes of electrical pulses 103 and 104 are selected in linear zones of said dielectric materials and very little or now energy loss occurs during propagation of such pulses.

As more practical example dielectric media between waveguides 101 and 102 can be filled with two layers of semiconductor material such as Si, wherein one of the layers is p doped and another one is n doped and layer's form p-n junction. Each of the pulses has amplitude of 0.5 V that allow minimal leak current through the junction during pulses propagation. Amplitudes are measured with respect to the common ground bus 100. Media inside each waveguide is air or some other insulating dielectric material.

Increase in transient voltage between waveguides above 0.5 V will cause significant current through the p-n junction. It is assumed that wave resistances of both waveguides are nearly identical and second pulse occurs before upcoming pulse reaches end of waveguide. At such conditions both pulses will reach some location at the same time. This location is defined by waveguides length, pulses propagation speed, and time delay between fronts of the pulses.

Transient voltage across p-n junction will exceed 0.5 V and reach nearly 1 V, which will cause significant transient current through p-n junction in location defined by collision of fronts of the pulses. Current density is defined by properties of p-n junction, shape of the fronts of the pulses, and electrical properties of the waveguides. This dependency can be illustrated by empirical equation: Iₘₐₓ˜C/(τL^{0.5}) where C is waveguide capacity per unit length, L is waveguide inductance per unit length, τ is length of pulse front.

Graph on FIG. 1 shows maximum transient voltage on the p-n junction as a function of position along the waveguide. Important aspect of the interference between these pulses is virtual independence of size on an area, where maximum power dissipation occurs, from duration of the pulses. Collision of two pulses causes increase in energy dissipation which results in partial reflection of upcoming portions of the pulses. Phase inversion reduces local field intensity and results in confinement of a region with maximum power dissipation to small area where the fronts of two colliding pulses intersect.

This focusing effect allows better control on size, intensity and position accuracy of the collision.

The energy focused by the collision is employed as an address signal to pinpoint virtually any location along the waveguide excluding end regions. These excluded regions are defined by duration of the pulses, and can be considered as a buffer area adjacent to pulse source.

Two waveguides design has an advantage of longer effective propagation distance comparing to a single waveguide design that will be described next. This advantage follows from ability to choose dielectric media for waveguide different than nonlinear medial of address transducer layer (Si in current example). Single waveguide design does not allow such clear physical separation between these two logical layers.

Important note for this example is requirement to have nonreflecting end on each waveguide to eliminate residual interference of sequential address signals with traces of address pulses from previous addressing cycles.

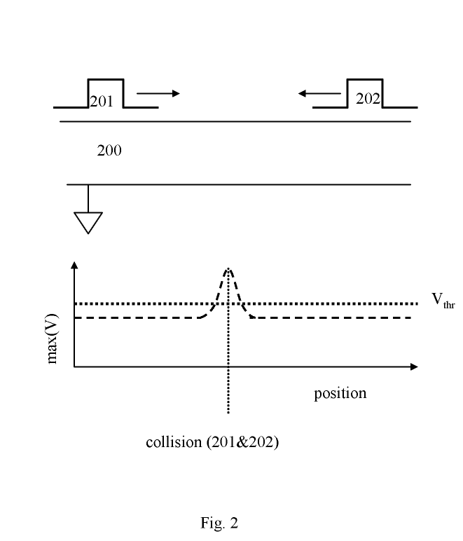

Conceptual diagram shown on FIG. 2 illustrates principle utilized in single waveguide design of address layer. Interference of two pulses occurs in the same media as their propagation, thus there is no physical separation between address transducer and address logical layers. Example shown on FIG. 2 uses electrical transmission line as a waveguide. The media inside the guide has very little or no energy absorption for pulses with low amplitude, such media as in the previous example can be made using p-n junction in Si layers.

Two voltage pulses 201 and 202 with nearly rectangular shape introduces into the waveguide 200 from opposite ends (pulse sources are not shown). Amplitude of each pulse is nearly 0.5 V, which causes negligible current through p-n junction in forward direction. Both pulses propagate toward each other and reach collision point where their fronts intersect. Due to interference field intensity nearly doubles and significant forward transient current passes through p-n junction.

All observations and relationships observed in case of two waveguides collision are true in this example as well. The only important distinction, the pulses always propagate through said nonlinear media, so stronger wave shape dispersion can be observed for pulses with larger amplitude.

Each source of address pulse has to have impedance equal to the waveguide to provide full absorption to incoming pulse and thus prevent undesirable interference with residual pulses.

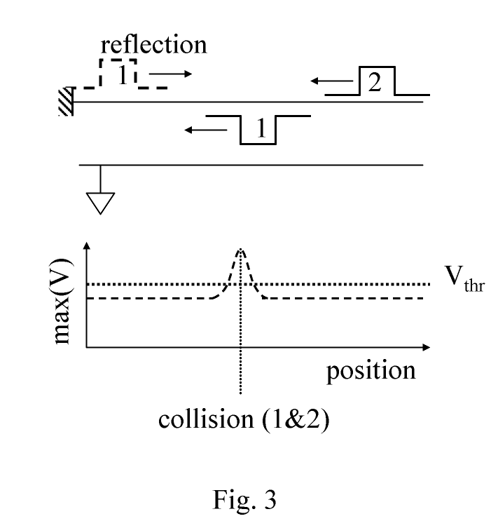

These two examples give significant inside view on operation of address layer. Several important conclusions can be observed. Pulses can be generated on the same side of the address waveguide. Phase of first pulse can be inversed with respect to the second pulse as shown on FIG. 3. An opposite end of the waveguide is closes and provides phase inversion and total reflection to incoming pulses. Collision is observed between the pulses when first pulse reflects from the end of waveguide and fronts of both pulses intersect. Due to inverse phase the first pulse experience minimal interaction with nonlinear media, which results in smaller shape dispersion.

In many cases propagation speed of energy pulse depends on mode or polarization of the pulse itself. This effect allows causing interference of two pulses that propagate in the same direction along address layer.

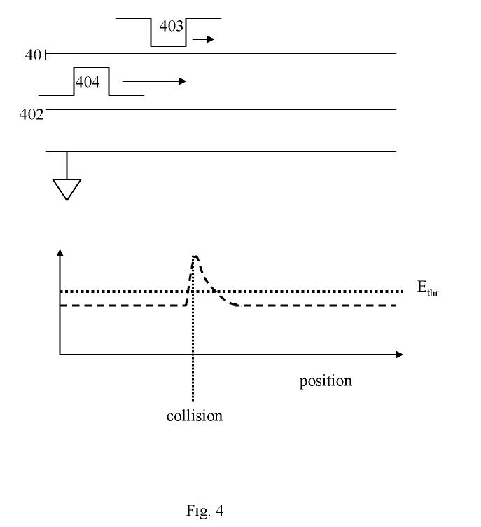

FIG. 4 illustrates this concept in case of two waveguides. Pulse propagation speed along waveguide 401 selected to be smaller than one of waveguide 402. Voltage pulse 404 propagates faster that first pulse 403. This results in collision between rear front of pulse 403 and forward front of pulse 404. Drawback of such design approach is decreased geometrical precision of address signal, which is caused by motion of collision point while total intensity of interference still remains in highly nonlinear zone.

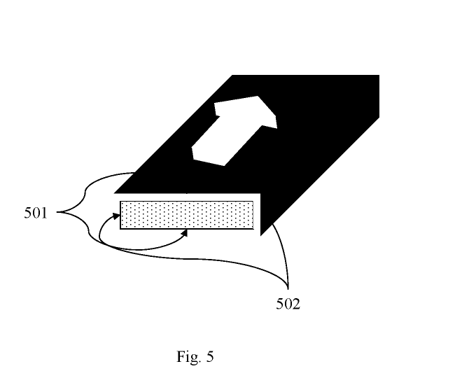

FIG. 5 shows application of the same principle for two-mode waveguide where wave with mode 502 has higher phase velocity than wave with mode 501.

Some of selected embodiments disclosed in this invention allow using back-to front interference described in last two examples, regardless of lower geometrical accuracy of addressing. One essential advantage of such back-to-front design is ability to employ single pulse source while still achieving quick addressing.

Designs that utilize two pulse sources located on opposite ends of waveguides can repeat addressing operation after rear front of second pulse reaches the end of waveguide.

Designs that utilize single pulse source and back-to front interference can repeat addressing operation after rear end of first pulse reaches the opposite end(s) of waveguide(s). This design approach is comparable in speed with first approach that utilizes two pulse sources.

Designs that utilize single pulse source and employ opposite end of waveguide for pulse reflection can repeat addressing operation only after rear front of second pulse completes roundtrip in two directions. This requires double the time of previous two designs.

### EXAMPLE 1

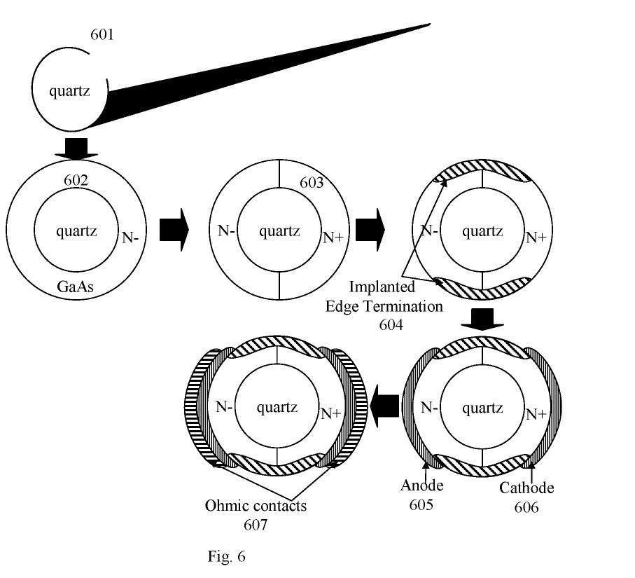

Construction of address layer operating in single dimension can be illustrated an example of fiber-like addressable material. FIG. 6 shows basic technological steps required to produce single fiber that can receive address signal at any location along its path. One practical use of such addressable fiber is thermal control applications.

Address transducer converts address signal into ohmic heat, and dynamic addressing of various locations allows precise control of heat flux produced by said locations.

Referring to FIG. 6, there is shown a schematic process of making electronically addressable fiber. Optical quartz fiber 601 has 50 micron in diameter and can be made by various techniques well known to anyone knowledgeable in area of fiber optics. Quartz fiber plays role of base substrate and provides mechanical strength and stability to the product. Another benefit of quartz substrate is high thermal stability and high melting point, which allows wide choice in selection technology for deposition of n-(undoped, residual n-type) GaAs cladding 602, this having Si dopant concentration 1×10¹⁵ cm⁻³. Choice of techniques for said deposition includes Liquid phase deposition, thermal evaporation, ion beam deposition, etc. Thermal annealing steps can be optionally incorporated into deposition process. Cladding 602 has thickness of 10 micrometers.

One segment 603 of the cladding perimeter (approximately 180°) doped using ion-beam implantation of Si to n+ (heavily doped n-type), where Si dopant concentration is 1×10¹⁸ cm⁻³ and implantation depth is 1 micrometer. Two segments 604 are passivated with insulating material or by means of ion implantation, this forms edge termination layer that reduces junction leakage.

Schottky junction is formed by deposition of anode 605 and cathode 606. Depositions are performed using ionbeam or thermal evaporation of metal (Ni as an example). Metal type selected to form Schottky junction with maximum barrier height, use of Cu in this case will restrict amplitudes of propagating pulses to 0.5 V. Optional ohmic contact layers can be deposited on top of cathode and anode to reduce ohmic losses of propagating pulses.

Described process allows creation of the fiber with length of several thousands meters. The technological process uses conveyer technology to sequentially perform all described steps on the same fiber. Nevertheless, this particular example of addressable fiber has practical length limitations. Electrical pulses initiated from single or opposite ends of the fiber experience loss of amplitude and front shape changes due to passive nature of transmission. So effectiveness of addressing will be limited to approximately 10 meters. Due to low dielectric losses in quartz and high charge mobility in GaAs the accuracy of linear address resolution at current state of the art of semiconductor components is limited by switching speed of pulse source.

As an example 300 picosecond pulses with 60 picosecond fronts can be produced using 81133A pulse generator manufactured by Agilent Technologies, Inc. Taking into account capacitance and inductance of the waveguide, phase velocity will be nearly 1.96 times smaller than wave propagation speed in quartz. Linear resolution of address impulse produces by front-to-front interference of two pulses is 5.9 mm.

It is possible to increase resolution by shaping the pulses entering the waveguide. Thus restriction of pulse front to only 30%-70% range reduces front timing to 30 picoseconds and address resolution to 3 mm.

Amount of energy diverted as the address impulse can be controlled by amplitude and bias of address pulses. In this example reverse breakdown voltage of Schottky junction is 25 V. Two pulse sources produces voltage pulses with amplitude of +20 V and have −22 V offset. Without interference each pulse propagates the waveguide with minimal distortion due to negatively offset junction. Front-to-front interference of these two pulses would produce +18 V peak of transient voltage in the waveguide. Nonlinearity of Schottky junction will suppress this peak and convert it to transient current that defines the address impulse.

### EXAMPLE 2

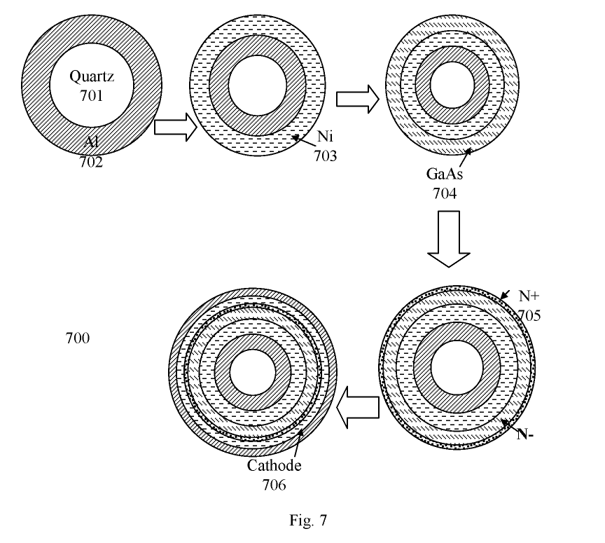

Another example, illustrated on FIG. 7, uses helically shaped substrate. 10 micrometer in diameter quartz fiber 701 is shaped to form 100 micron in diameter and 25 micron pitch spiral 700. Metal multilayer anode deposited directly on quartz surface using thermal evaporation of 3 micrometers of Al 702 and 500 nanometers of Ni 703. After each deposition optional step of thermal annealing is included.

3 micrometers layer 704 of n-type undoped GaAs is grown on anode, with Si dopant concentration 1×10¹⁵ cm⁻³, followed by ion implantation 705 of 1 micron Si dopant to reach concentration 1×10¹⁸ cm⁻³.

500 nanometer Ni cathode form Schottky junction and additional ohmic 2 micron thick layer of Al deposited to complete cathode. Additional insulation layer may be deposited on top.

Spiral shape of this addressable fiber provides additional flexibility and gives the material added mechanical stability. Passing the fiber through Tygon® allows formation of very durable fiber that retains its transmission characteristics after significant mechanical processing. In addition, lateral precision of addressing reduced to 0.5 mm for the same 60 picoseconds front.

Active Waveguide

The subject of previous disclosures and samples was focused on demonstration of interference of electrical fronts in nonlinear media, and particularly utilized one-dimensional wave propagation inside fibers. According to these examples efficient propagation distance of such addressable fibers is limited by dissipation of wave energy in dielectric and/or nonlinear transducer layer.

The present invention is not limited to these cases. Non-linear transducer layer of early examples was constructed to reproduce Schottky effect. In case when longer address space is required tunneling effect can be used instead. Pulse propagating in waveguide, where in waveguide media has tunneling properties, has to have initial amplitude in area of negative resistance. Such pulse will experience strong front-shaping effect that produce sharper front. This front propagates throughout the waveguide without attenuation.

### EXAMPLE 3

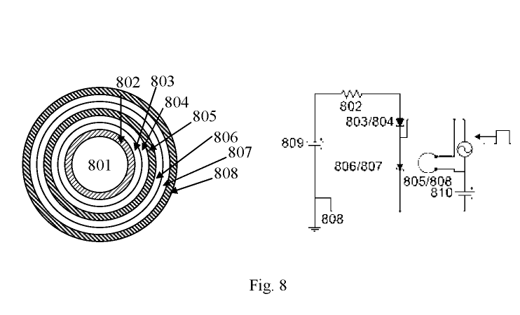

Addressable fiber utilizing tunnel effect is shown on FIG. 8. Metal multilayer anode 802 is deposited on substrate 801. Tunnel layer is formed by junction of p-type GaSb layer 803 and n-type InAs layer 804. Multilayer metal waveguide 805 forms cathode of tunnel layer and anode of Schottky layer. Schottky layer is formed by N− type GaAs layer 806 and N+ type GaAs layer 807. Common cathode is formed by multilayer metal layer 808. Optional outer insulation layer is not shown. Composition of the layers can be adjusted for each specific application and their structure can be chosen from known public and proprietary publications describing production of tunneling and schottky diodes, some such examples includes in referred documents.

Referring to FIG. 8, there is offset voltage source 809 that allows adjustment of tunneling current in rest state, and offset voltage source 810 that adjust working region of schottky junction.

This example is not limited to use of specified materials, and other materials can be employed. In some cases schottky junction can be replaced with Zener, or p-n diode, or PiN diode structure.

Optical fiber

Addressable fiber material is not limited to use of electromagnetic waveguides. Addressing functions can be equally achieved using front-to-front or front-to-back interference of monochromatic light pulses propagating in Kerr media.

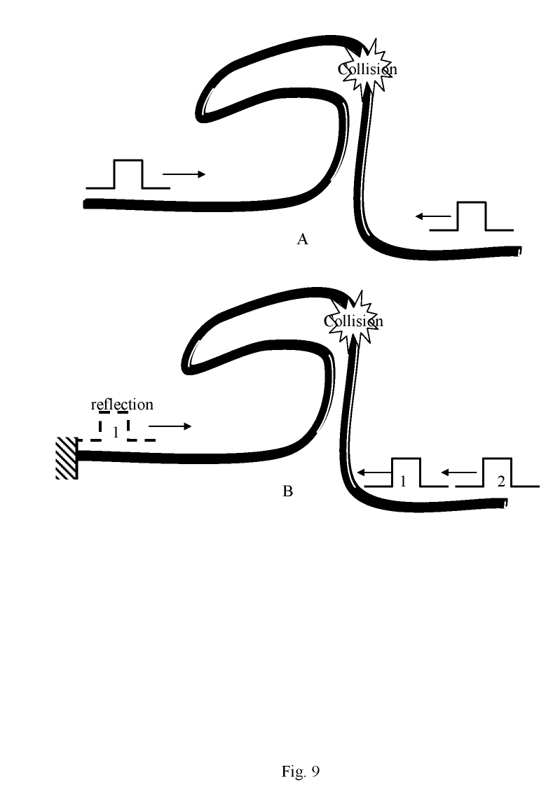

FIG. 9 illustrates this concept. Referring to FIG. 9, there are two cases shown. In case A light pulses enter the optical waveguide from opposite ends. Interference of fronts of these pulses causes reduction of refraction index of waveguide media, which cancels full internal reflection of the fiber and allows light energy escape. In case B both pulses enter waveguide through the same end. Opposite end of the waveguide has total reflection that inverse direction of pulse propagation. Interference of fronts of the pulses changes refraction index of Kerr media allowing escape of light energy through cladding.

### EXAMPLE 4

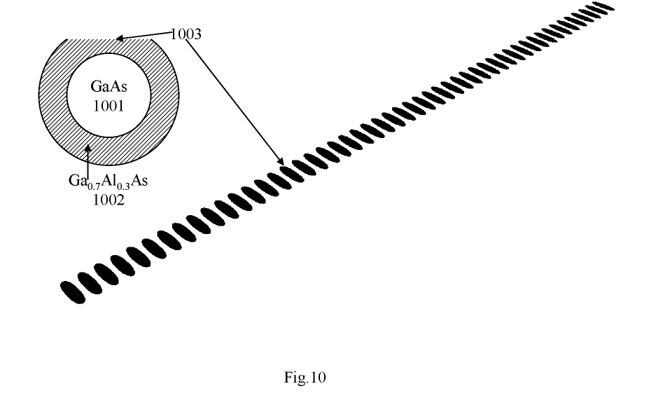

Optical fiber shown on FIG. 10 illustrates present embodiment. The core 1001 of the fiber made of undoped n-type of GaAs with refraction index n=3.46 and has diameter 5 micrometers. The core surrounded by cladding 1002 of Ga_{0.7}Al_{0.3}As with refraction index n₁=3.28 and thickness of 5 micron. This waveguide fiber maintains full internal reflection conditions for curvature radius larger than 96 micron. The fiber forms spiral with diameter 200 micrometers and pitch 20 micrometers.

Th cladding layer cleaved on one side to form nearly flat output window 1003.

The intensity of address impulse will quadratically increase with power of addressing pulses. Interference of two pulses doubles intensity of electric field in the core and causes transfer of energy into the cladding. 1 pS pulses with energy 1 nJ from Nd:YAG laser reduce refractive index of the core by 0.005 that causes transfer of 50% of light into the cladding and results in irradiation of 1 nJ of light through output window.

Lateral resolution of the addressable fiber in this example is 300 micrometers along the fiber path and 20 micrometers along the spiral direction.

Piezoelectric Fiber

Another implementation of addressable fiber uses electromechanical sheer waves propagating along a surface of piezoelectric material. Unlike previous embodiments, the speed of pulse propagation is limited by phase speed of sheer waves in the waveguide. In order to increase effective propagating distance of such electromechanical waves the waveguide can optionally comprise electrical layers with negative resistance such as tunnel layer of example 3. Wide selections of available piezo materials allow create multiple custom addressable fibers for various applications. Following example illustrates principle of design of one of such addressable fibers.

### EXAMPLE 5

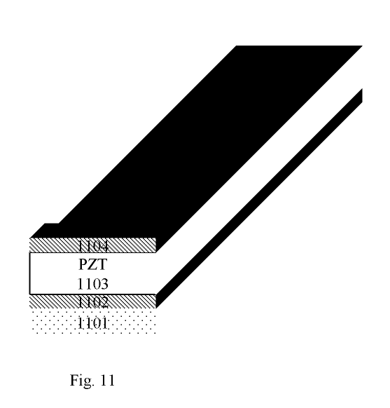

Layer diagram of the fiber shown on FIG. 11. Borosilicate substrate 1101 carries PZT structure 1103 with metal electrodes 1102 and 1104 and thickness 1.2 micrometers. Electrode 1104 represents 20-nm-thick YBa₂Cu₃O₇ film and 1 micrometer thick contact electrode Pt/Ta that forms interdigital OLE_LINKlpiezoelectric transducerOLE_LINK1. Opposite end of the waveguide (not shown on the FIG. 11) has identical electrode 1104. Conductivity of 20-nm-thick YBa₂Cu₃O₇ is sufficient to achieve polarization of PZT layer, nevertheless its conductivity is not sufficient to counteract charge wave of surface potential during propagation of electromechanical pulses.

Propagation speed for sheer wave in the waveguide is 3×10³ m/s. Two pulses with length 10 nS were generated by applying 20V impulses to electrodes 1104. Geometrical resolution of address impulse obtained at collision these two pulses was 30 micrometers.

The samples and embodiments of the present invention do not intend to limit it to the cases of interference between pulses of waves of the same type. It is well known to one experienced in material science that nonlinear properties of propagation media allow collisions between heterogeneous by nature waves. Some examples of such collisions include interaction between waves with different wavelength in Kerr media, interaction of photons with acoustical waves, etc.

Two-dimensional continuously addressable active materials

Two-dimensional continuously addressable materials have continuous (non-discrete) address space along first dimension and discrete or non-discrete address space along second dimension. Behavior of each location of the surface of the material is monitored and or controlled by controller device that is either distributed along the surface of the material or has standalone location.

Hybrid Addressing Layer

This section describes materials that form two-dimensional surface with continuous address space along first dimension and discrete address space along second dimension. This material or device is a composition of single-dimensional addressable materials that were described in previous sections. The term fiber will be applied as single dimensional addressable active material for the length of this section.

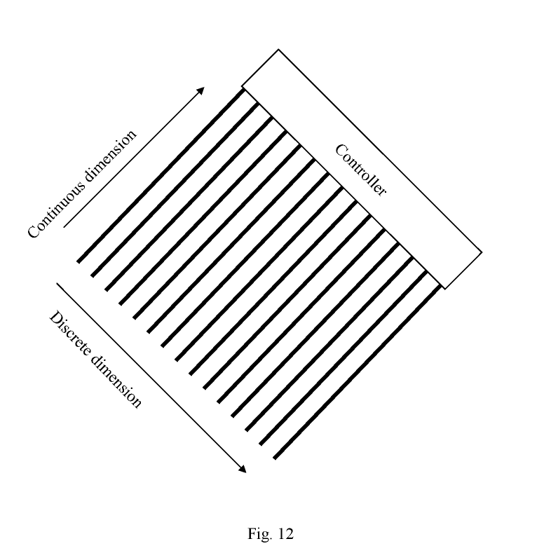

Arrangement of fibers defines addressing structure of this material. In a simplest case all fibers have parallel arrangement on the surface as it is shown on FIG. 12. Each fiber takes its own data channel in communication with controller device that manages the behavior of the material. Controller device can be distributed among the discrete dimension as it is shown on the FIG. 12 or can be connected to each fiber through common communication bus.

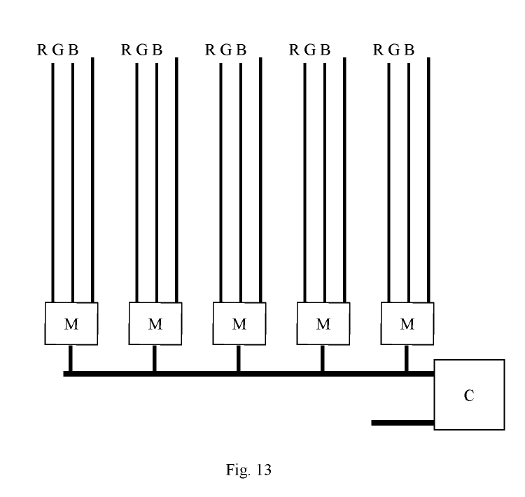

FIG. 13 illustrates the design where fibers are grouped with intermediate controller modules. It is obvious that any other arrangement and grouping of fibers and control modules is also possible, and final design shall be dictated by specific application. The figure shows fibers “R”, “G” and “B” that are grouped together and attached to single control module “M”. These control modules in turn has link with next control node “C”, etc.

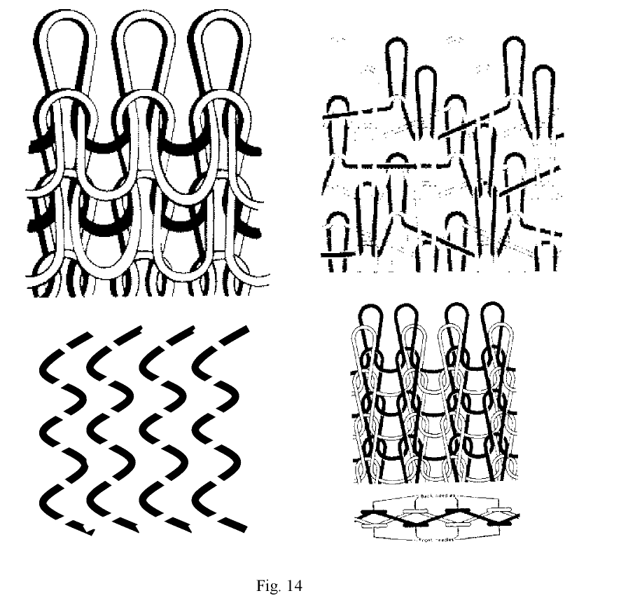

Fibers arrangement can be customized for each individual application and some examples of such arrangements are shown on FIG. 14. It was shown in previous embodiments how to produce durable and flexible fibers. This allows to layout these fibers into configuration of woven fabric. The fabric-like structures increases fiber length per surface area. This allows increase in addressing precision and energy density per surface area. Selection of particular layout pattern can be dictated by desired curvature of waveguide. Some fabric stales have linear fragments alternating with narrow loops. These layouts can be favorable for devices such as flat-screen displays, where light escape segments of the waveguides located on those loops, which results in lower requirements to the wave front.

Two-Dimensionally Continuous Addressing

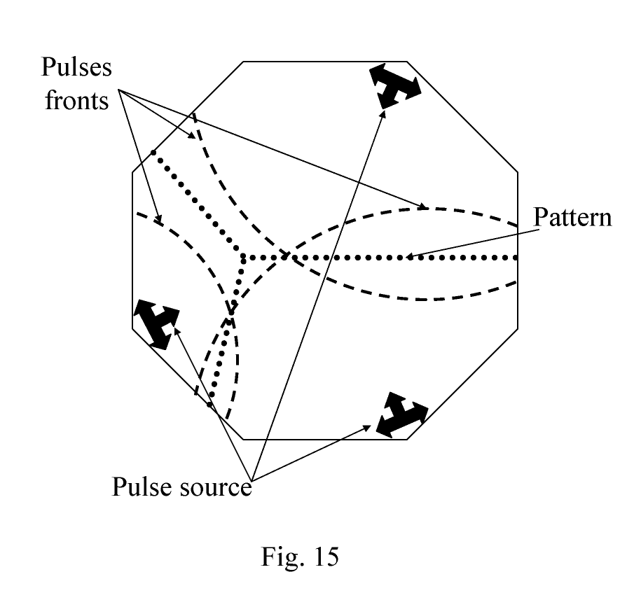

Apparatus that uses energy pulses propagating in nonparallel directions allows design of two-dimensional continuous addressing layer. Addressing schema for such layer can be of two different types. First of them is pattern type and second is vector type. Pattern type allows simultaneous addressing of multiple surface areas of the layer that are forming predefined pattern. This type of addressing is achievable with use of crossing fronts of energy pulses as it is shown on FIG. 15. With various number and placement of pulse sources different types of patterns can be obtained. Use of continuous source of energy waves allows generating various patters using steady waves in the address layer.

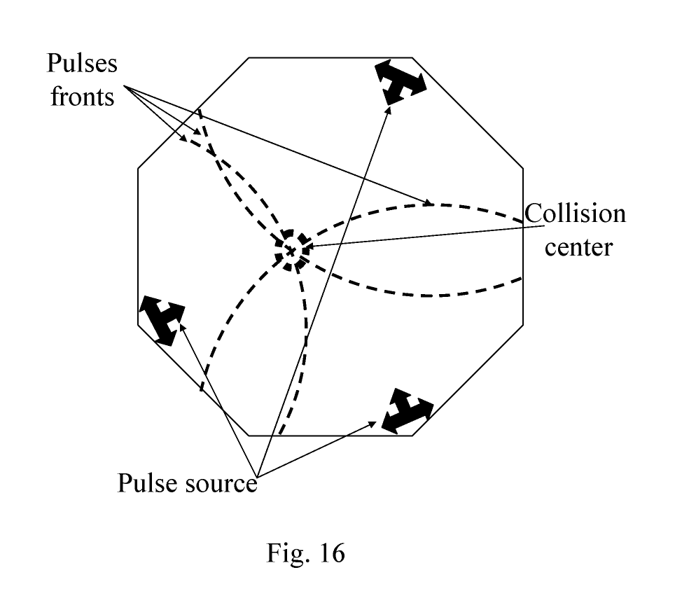

Vector type addresses single segment of addressing layer. This type of addressing is achievable with use of energy front's collision as it is shown on FIG. 16. Energy density in the collision center exceeds the threshold of address transducer that causes part of this energy to be absorbed by address transducer layer.

In order to achieve geometrically constraint and focused address impulse it is important in most cases to create addressing pulses with strait fronts. While it is possible to consider interference of four or even larger number of addressing pulses, in practice such designs will require to tuning of relative timing of the pulses.

From practical considerations following embodiments are restricted to interference of three addressing pulses propagation in bound two-dimensional layers.

### EXAMPLE 6

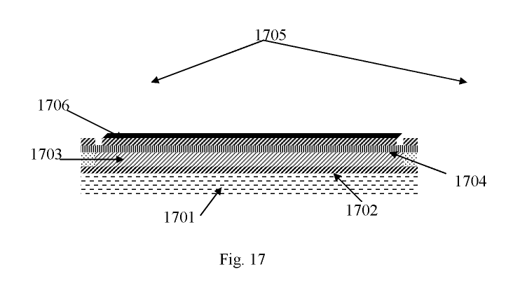

FIG. 17 shows layer model of two-dimensional address layer that employs planar waveguide for sheer waves in piezo media. Borosilicate glass substrate 1701 supports common multilayer metal electrode 1702. Piezo material such as PZT forms planar layer 1703. On top surface of layer 1703 formed layer 1704 that represents planar Zener diode. Two opposite sides of the waveguide are parallel and have interdigital piezoelectric transducers 1705 located in parallel to each other. Third transducer 1706 located on the edge that orthogonal to the first two transducers. Layer 1704 is formed on top of undoped n-type silicone which has low concentration of carriers. During operation of the address layer Zener diode layer has negative voltage offset that causes depletion of n- layer interfacing with piezo layer. This prevents lateral currents induced by surface charge wave.

Transducers 1705 and 1706 produce three independent rectangular pulses. Fronts of the pulses have length of 100 nS. Each pulse produced by transducers 1705 creates sheer wave with electrical amplitude 10 V. The pulse produced by transducer 1706 has total length of 1 microsecond. Front-to-front interference of two pulses produced by transducers 1705 creates transient peak with amplitude of 20 V. This transient peak has linear form that parallel to propagation vector of sheer pulse produced by transducer 1706. At current location of intersection of all three sheer pulses transient deformation peak could reach 30 V in amplitude.

Breakdown voltage of Zener diode layer is 20.2 V. This causes transient current to pass through the diode layer and also causes partial reflection of the pulses. Due to nonlinear behavior of Zener layer the size of addressing impulse is limited to 3×0.3 mm area. In order to reduce this size the length of the third sheer pulse should be reduced, because in described example interference has front-to-front-ridge type.

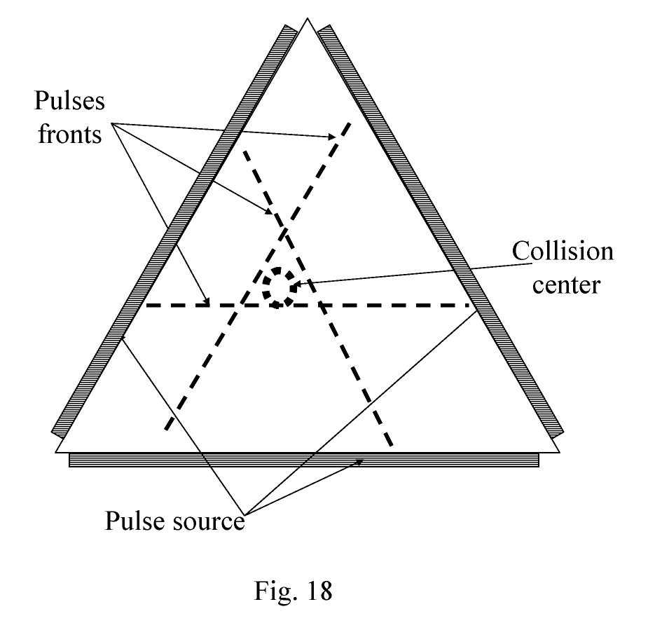

To increase address resolution without reducing pulse width the address layer should employ front-to-front interference only. An example of such layer is shown on FIG. 18. Pulse transducers are located in triangular pattern so no parallel pulses are created.

Designs similar to one shown in the previous example can utilize various alternative semiconductor structures such as Schottky junction, Fermi-FET, etc. to serve as a transducer of acoustic address impulse to electrical signal.

Continuous Address Transducers

Address transducer layer geometrically follows the continuous address layer. It has nonlinear characteristics and selectively responds on energy density in the address layer. There are multiple possible implementations of this logical layer and some of them were described already. Each implementation is targeted to operate with particular type of addressing layer.

### EXAMPLE 7

This transducer layer apparatus has one- or two- dimensional surface-acoustic wave address layer that positions an address pin in one or two dimensions.

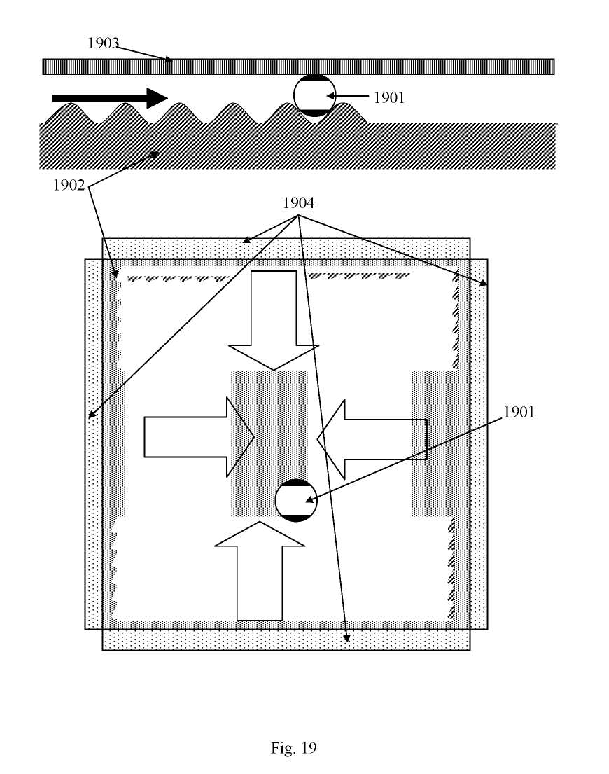

FIG. 19 illustrates the principle of design of the apparatus. Address pin 1901 is Au nanosphere has diameter of 300 nm. It is located on top of address layer 1902 and functional plane 1903. The shape and material of the pin 1901 can be alternatively selected specifically for individual applications. Some examples are gold ball, fullerene sphere or cylinder, tungsten, silicon, SiN cones or pyramids, glass, quartz, etc. Functional plain 1902 may have complex structure and functionality, but for purpose of this example can be considered made of thin layer of glass. Layout of the two-dimensional version of this transducer layer has SAW transducers 1904 located on opposite sides of the address layer. Minimum number of transducers in two-dimensional version is three. Transducers initiate pulses of surface waves that force the address pin to move along the functional plane. Sending waves from different transducers allows positioning of the pin at any predetermined location.

Advantage of such transducer layer in comparison with previous embodiments is extreme addressing accuracy that defined by contact area of the pin and the functional layer. In present example it can be as small as few nanometers.

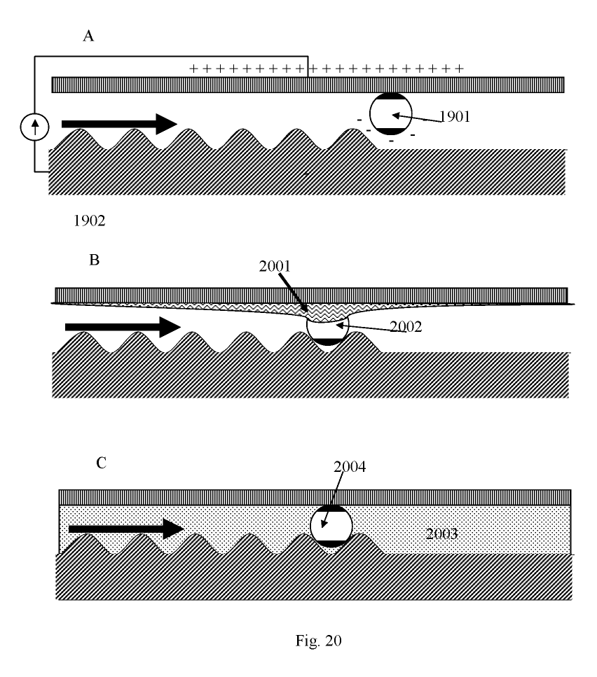

The transducer layer does not impose any limitations on the structure and functions of the functional layer. Functional layer can additionally perform load function by applying pressure on the addressing pin that causes increase in friction between the pin and substrate. There are some possible designs where pin has negative or zero force of interaction with the address layer. These examples are shown on FIG. 20. Functional layer of FIG. 20(A) is nonconductive or has relatively high resistance. It has an electric potential with respect to the address layer 1902. When pin 1901 contacts the address layer it receives electric charge opposite to the charge of the functional layer. Due to electrical repulsion the pin adheres to the functional layer and repels from the address layer.

Functional layer of FIG. 20(B) has high affinity to the liquid 2001. The pin 2002 also has high affinity to the liquid. This causes the pin to be adhered to the surface of the functional layer, and makes possible to reduce friction between address layer and the pin. Alternatively the pin may have low affinity to the liquid. This will dramatically reduce friction between the functional layer and the pin, and additionally increase friction between pin and the address layer.

Functional layer of FIG. 20(C) fills the volume between itself and the address layer with liquid 2003. There are several possible combinations of affinity to the liquid of the pin 2004, the address, and the functional layers. Each of them may have a special application. Consider the case when liquid has high affinity to the address and the functional layers, and low affinity to the pin. This dramatically reduces friction forces for the pin.

### EXAMPLE 8

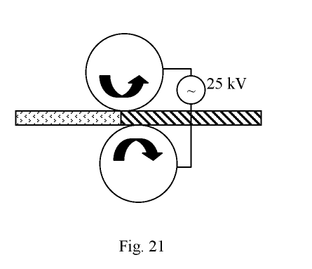

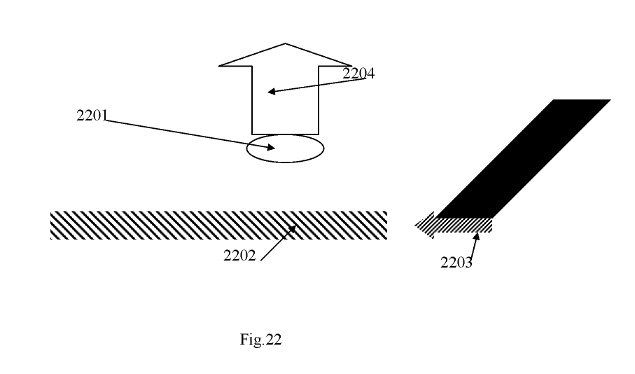

The address transducer layer of this example can be chosen from examples 6 or 7. It delivers 20 V address impulse to the functional layer of this example. The functional layer herein defined by one- or two-dimensional optical waveguide. Two-dimensional example uses planar silica film with thickness of 1.2 micron that has been poled by alternating high voltage source as shown on FIG. 21. Poling creates electro-optical zones oriented at 45° angles with respect to the film normal. Poling period can be constant across the film or may be altered to create alternating domains with 639 nm, 565 nm, and 465 nm poling period. The poling technique is well known to one experienced in the art and some references on poling processes can be found at U.S. Pat. No. 6,522,794. Top side of this functional layer has uniformly deposited transparent electrode layer. Single or multicolor light focused on the edge of the functional layer as shown on FIG. 22. Address impulse from underlying address transducer layer delivers electrical polarization impulse to specific poled domain 2201 of the functional layer 2202. This causes redirection of light beam 2203 that have corresponding wavelength. Redirected light beam 2204 escapes from waveguide 2202.

Addressable material with similar functional layer can be utilized for construction of flat display devices. Time required to render individual image element depend of wave propagation speed of address layer. Small displays can be easily implemented using acoustical type of address layer similar to described in examples 6 and 7. Such display devices will have extremely high resolution that only limited by efficiency of poling structure. Large displays can use optical or electromagnetic types of address layers that are similar to examples 3 and 4. Time to render a single image element on display of one meter in size is only 10 nS.

Semiconductor transducer device has a barrier that extended along one or two dimensions of the address bus. Energy pulse below effective threshold level of the barrier has low probability to penetrate the barrier. As a result of interference in the address bus the amplitude rises in the location of pulse's interference. When energy level approaches and exceeds the barrier threshold the probability of barrier penetration rises exponentially that results in significant transient current through the barrier. When Fermi levels on other sides of barrier are close to each other, the barrier shall be created to prevent spontaneous migration of energy carriers.

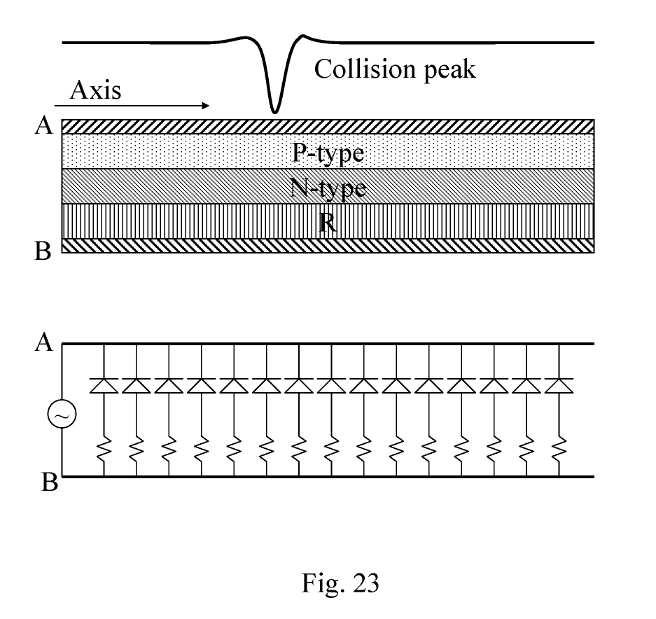

In case the Fermi levels are distinct significantly this difference itself creates a potential barrier for energy carriers. Only carriers with sufficient energy will migrate through the system. Simple practical example of such device is illustrated on FIG. 23. In this example p-n junction forms the energetic barrier. In case of silicon electrical signals with amplitude below approximately +0.4 V will have little or no dissipation when travel through the device. Such conditions can be achieved by applying appropriate bias voltage that shifts the barrier into depletion zone. Collision peak with amplitude exceeding the barrier height causes energy dissipation in resistive layer R. Equivalent discrete elements schematic of this device is shown in lower part of the drawing. Electrical pulse travels between conductors A and B along the main axis of the device. Interference with incoming pulse causes the collision peak, which dumps excessive energy into resistive layer R. This example is just an illustration of the principle of the transducer layer operation, and does not limit the invention to this particular implementation.

This example can use light emitting diode structure instead of standard diode. In this case depletion zone will work as a resistive load, which performs transformation of pulse's energy into light. Resistive layer does not necessary convert pulse's energy into heat. It is shown as some example structure that performs implementation specific functions in response to the collision peak adsorption.

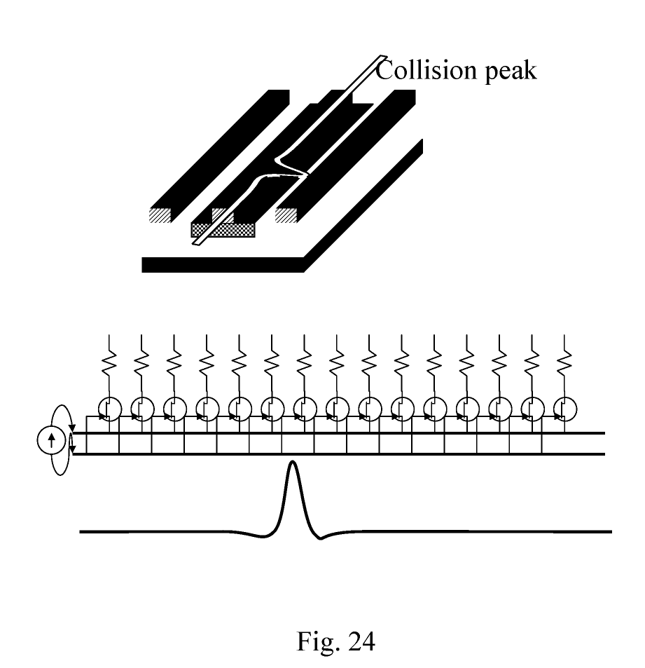

Another example that uses semiconductor materials to satisfy requirements for the address transducer operations is shown on FIG. 24. This example uses flat one-dimensional FET transistor. Source and the Gate of this transistor form the waveguide for logical address layer. Interference peak is amplified by the transistor, which causes increase in drain current in appropriate lateral location. It is obvious that other types of transistors can be used in similar designs.

All examples described above use an assumption that normal propagation time is significantly less than tangential propagation time. This assumption can be achieved by using geometry of elements that have small normal dimensions in comparison with lateral dimensions, by using materials with anisotropic properties, or using semiconductor layers with low carrier concentration.

Flexible Address Layer

Advances in polymer chemistry created new types of polymer materials that in addition to significant flexibility possess electro-mechanical and electro-optical properties. Some of these materials can be effectively employed in previous embodiments. PVDF laminate can be used as a piezoelectric component of acoustical address layer used in examples 6 through 8. This allows replacing solid substrates with polymer materials this constructing flexible and inexpensive two dimensional address layer. The same materials can be used in fiber design to create addressable one-dimensional materials.

Functional Layer

This section describes some examples of functional layer that illustrate usefulness of addressable materials. The structure of these layers is equally is equally applicable to one-dimensional and two-dimensional address layers.

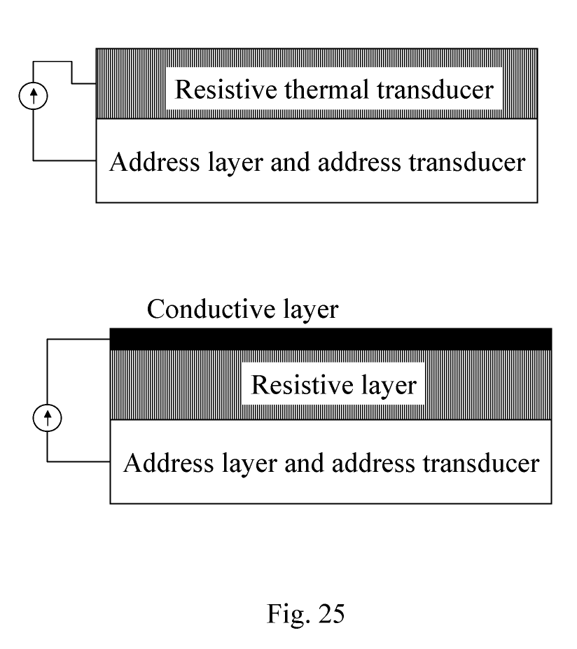

Resistive thermal transducer Functional layer made of material with relatively high resistance may operate as thermal transducer converting amplified or un-amplified address signal into thermal energy. This resistive layer can be deposited on conductive layer that provides low lateral resistance as it is shown on FIG. 25.

Large Surface Area LED

Functional layer designed as large surface area light emitting diode (LED). One electrode of the LED is merged with address transducer. Address signal causes current through the address transducer and the LED. The density of the current reaches the maximum at the addressed location. Special design consideration should be taken to create LED layer with minimum thickness. This will allow achieving maximum current density through the LED surface and highest resolution.

Sensor Data Transducer Layer

Address transducer layer allows creation of localized energy impulses diverted to functional layer. Functional layer represents two types of functions that are distinct from data flow perspective. Execution or work functions receive address information that can also contain data about execution (i.e. amplitude of address impulse can carry data about amount of heat or light intensity that needs to be produced by functional layer). As another example common bias voltage applied to functional layer provides information on the same quantities and should be synchronized with addressing operations.

Sensor functions of functional layer should return data about current status of particular address position. As an example, functional layer of example 8 can be easily replaced with photo resistive material. In this case current through common top electrode of functional layer will be dependent on amount of light exposure at current address location. This allows query operations on functional layer. Addressing specific location information can be retrieved from common data layer.

Functional layer can have interlaced structure that has sensory and work regions. Such layer is addressed through single address layer and address transducer. Transducer design can be uniform or be interlaced to match pattern of the functional layer. Some examples of such systems are resistive thermo transducer with temperature sensor regions; LED transducer with photo sensor regions, etc. Address layer addresses different locations to retrieve sensory data and this data can be used to affect operation of work regions of the functional layer.

LCD Transducer

Functional layer is designed as liquid crystal display (LCD) device. The resistance of liquid crystals usually very high, it is easy to achieve highly focused addressing with this type of functional layer. Address impulse is used to turn on a point on the LCD surface. To turn off the point it is possible to use another addressing pulse or use common electrode of the LCD to reset the whole surface.

Electric Charge Transducer

Functional layer of non-conductive or very low conductivity material is used as electric charge transducer. The work layer captures electrons emitted by address transducer. Functional layer preserves pattern of electric charge distribution, and can be used separately from the rest of the apparatus or as its integral part.

Charge-Induced Vapor Condensation of Evaporated Materials

Work layer described in the previous embodiment additionally works as a transducer for material deposition. Placed in volume with vapors of charged ions (such as evaporated metals, ITO, carbon, and other chemical compounds) it induces condensation of the vapors at charged or locations, which allows creation of custom patterns of chemical compound and materials on surface of the functional layer.

Current and Electrochemical Transducer

Low conductivity functional layer is exposed to electrolyte with chemical compounds and or biochemical molecules and or macromolecules. Work layer allows conducting site-specific electrochemical reactions on its surface as well as custom site deterministic deposition of the chemical s.

Addressable Active Thermal Materials

Addressable active thermal material is an example of one of possible areas of application of addressable active materials. These materials are targeted to tasks of precision control and monitoring of heat propagation and temperature distribution along the surface of the material.

One-Dimensional Thermal Material

Single dimensional addressable active thermal material is an apparatus that has continuous path on the surface where the temperature at any point of this path behaves in accordance with controlling algorithm regardless of influence of external factors. Surface of this material has a temperature detector that provides data about temperature at any point along the surface of this material. Construction also contains thermal control element that supplies and/or removes heat to any point of the surface. Temperature sensor and thermal control element are coupled through a controller and or directly.

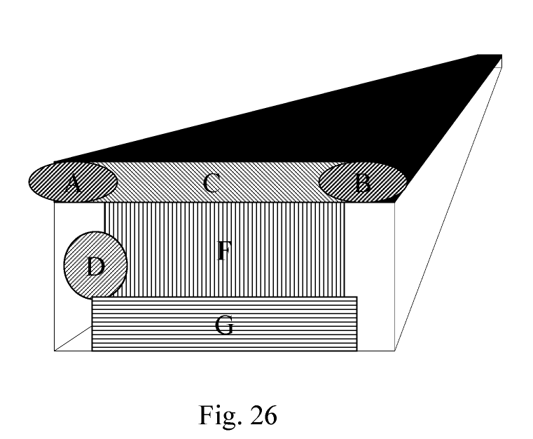

Temperature sensor and thermal control element represent the functional layer. FIG. 26 illustrates common construction features of the material. Temperature detector C uses address layer A and data layer B to transmit temperature data for each linear location along the surface of the detector. Address layer sends select signal along the detector C that causes addressing of specific areas of the detector. Data received by those segments are transmitted through data layer B to a controller device. The controller device is an analog or digital apparatus that uses sensory data to determine control signals for each segment of thermal control element F. This signal is delivered to a particular segment of the element F through control data layer D. Heat transfer along the apparatus established through heat exchange layer G. This layer transmits heat toward or away from each segment of the layer F.

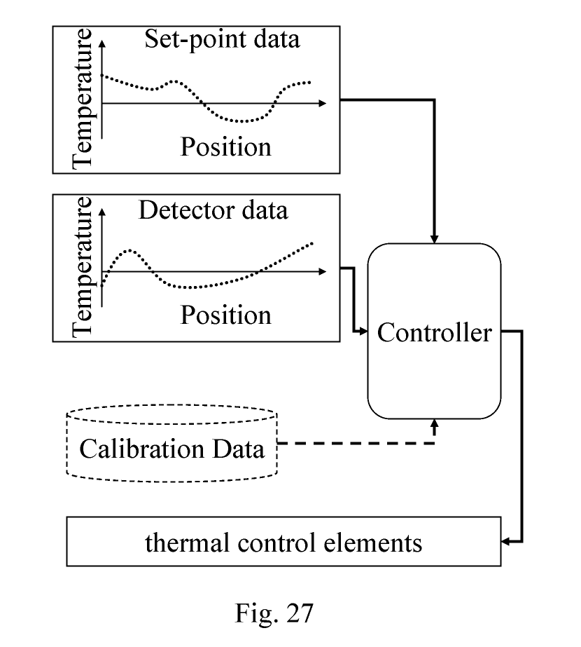

FIG. 27 illustrates controller's operation. Set-point data in digital or analog form represent desired temperature distribution along the surface of the apparatus. This distribution can be reduced to constant that represent constant temperature in all segments of the surface. Alternatively this distribution can be a static function or time dependent function. Real-time temperature distribution data are received from temperature detector layer. These data are presented in digital or analog form. Controller algorithm is responsible for feedback operations.

Two-Dimensional Thermal Material

Two-dimensional addressable thermal material has a continuous surface where temperature in each point behaves in accordance with controlling algorithm regardless of external factors. Surface of this material has temperature detector that provides temperature data for any element of the surface. Construction may contain an addressable array of thermal control elements or continuous thermal control layer. This control layer is capable of supplying and/or removing heat to corresponding location of the surface. Temperature detector and thermal control layers are coupled through a controller.

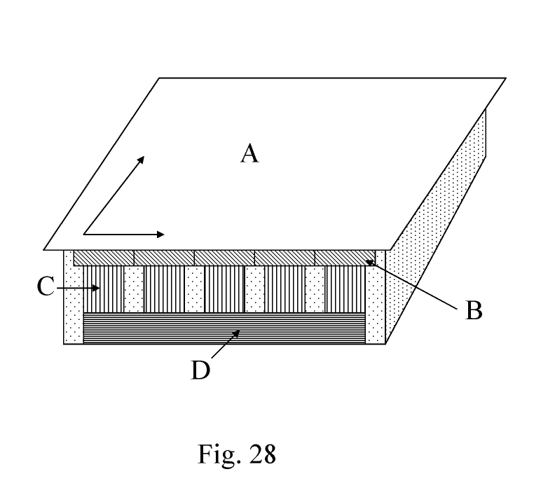

FIG. 28 illustrates common construction of such material. Addressable temperature detector B detects temperature of each segment of surface A. Heat flux toward or away from each segment of the surface actuated by thermal control layer C. Integral heat transfer toward and/or away from the material established through heat transfer layer D.

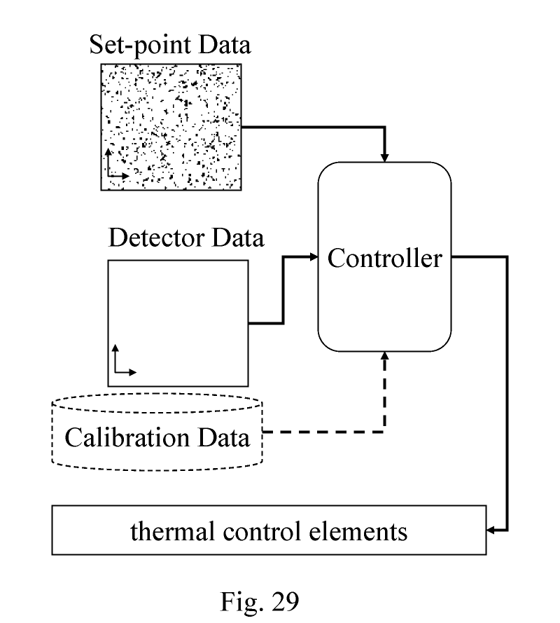

Controller operations are illustrated on FIG. 29. Set-point data in digital or analog form represent 2-D image of desired temperature distribution across the surface. Real-time data from temperature detector supplies 2-D image of current temperature distribution of the surface. Controller processes these data. Controller algorithm provides feedback that may use calibration data for the material.

Single-surface addressable active thermal material

Both one- and two- dimensional addressable materials can be used to create components and parts with single active surface. Specific physical requirements for such parts will determine use of one- or two- dimensional material. Combination of multiple single-dimensional material fragments allows coverage of two-dimensional surface of specific physical body.

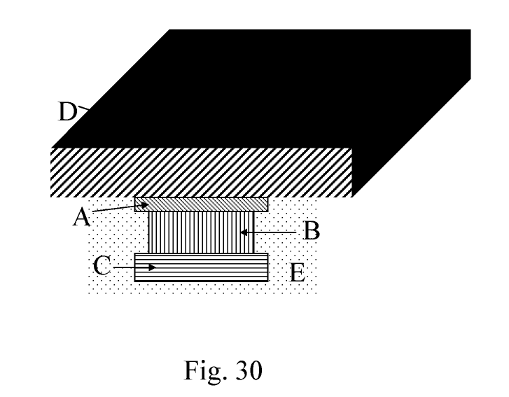

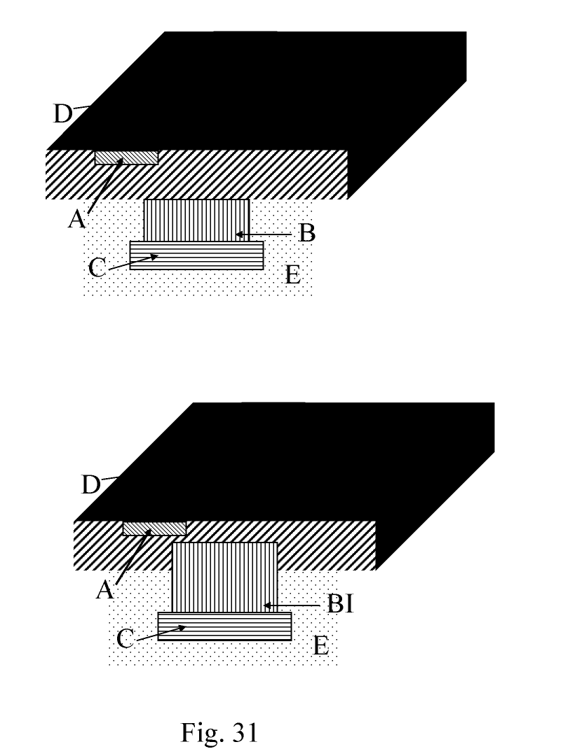

FIGS. 30 and 31 illustrate details of construction of physical body with single dimensional addressable thermal material. On FIG. 30 addressable material ABC attached to inner surface of the body D. Outer surface of the body can be used according to its primary purpose. Temperature detector A is mounted on inner surface of the body D. Thermal control element B controls the heat flux toward and away from D. Heat transfer layer C transfers heat toward or away from the assembly. Optional protective layer E protects the assembly. It may serve for mechanical, moisture, electrical, and/or thermal protection.

Temperature detector may be positioned on the outer side of the body. This design is illustrated on FIG. 31. Detector A is mounted on outer surface D of the body. This is possible if such design does not conflict with the primary functions of the body D. Thermal control element B is placed on inner side of the body. It is also possible to design body D in such a way that thermal control element BI will be indented into inner surface of D.

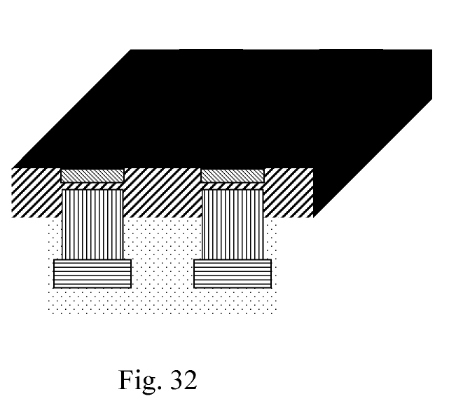

Multiple single dimensional fragments of addressable material may be positioned on a single surface of the physical body. An example of such design is shown on FIG. 32.

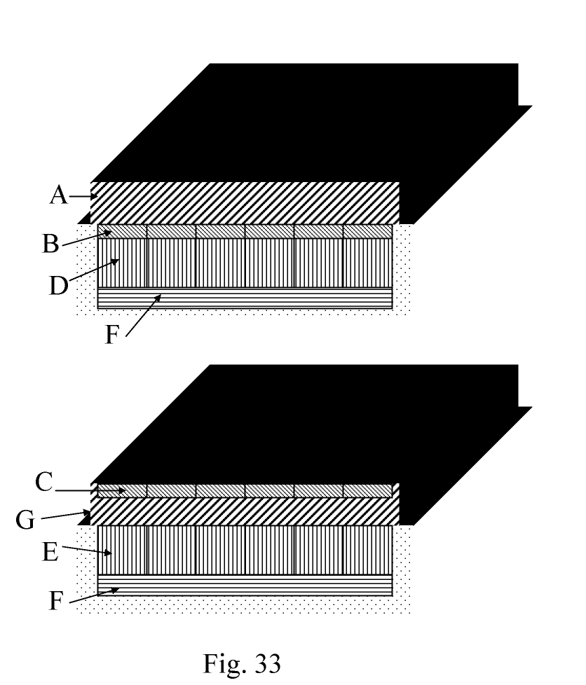

Two-dimensional addressable active material can be used in combination with single surface of a physical component. Several possible designs are illustrated on FIG. 33. Physical body A is mounted on top of 2-D addressable material. Temperature detector B reads temperature of inner layer of the part. Thermal control elements D and heat transfer layer F operates according to the description in previous embodiment. Alternatively temperature detector C may be placed on outer surface of the physical body G and have separate address layer. Thermal control elements E and heat transfer layer Fare places on inner surface of the body.

Multi-Surface Addressable Active Thermal Material

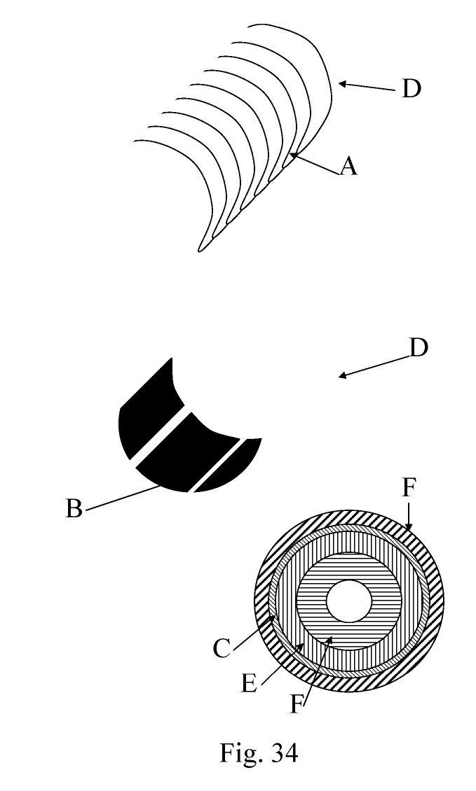

Design of components and parts with addressable thermal materials can be extended to cases of complex shapes. Addressable thermal materials can be integrated into various designs. FIG. 34 shows some examples of such integration. Addressable thermal material A is placed on outer surface of a body D. Temperature detector can be mounted on the same outer surface. Body D can be modified to allow mount of the detector on its inner surface. Alternatively addressable thermal material B can be positioned on inner surface of the body D, and its temperature detector mounted on its inner or outer surface. Each detail can be integrated with multiple or single addressable thermal material fragments.

FIG. 34 shows an example of integration of an entire inner volume of body F with single addressable thermal material. Temperature detector C monitors temperature of internal surface of the body. Thermal control element E forms continuous surface inside. Its inner portion is connected with heat transfer layer F.

Flexibility in use of addressable thermal materials allows manufacturing of parts with virtually any shape and design. Addressable thermal material may be places inside the parts and/or on their outer surface. An example of such design is a solid block of some material filled with addressable thermal material. If this block is configured to single temperature mode, it will attempt to maintain identical temperature at all points of its surface regardless of edge conditions.

Addressable Active Thermal Material with Heat Flux Sensor

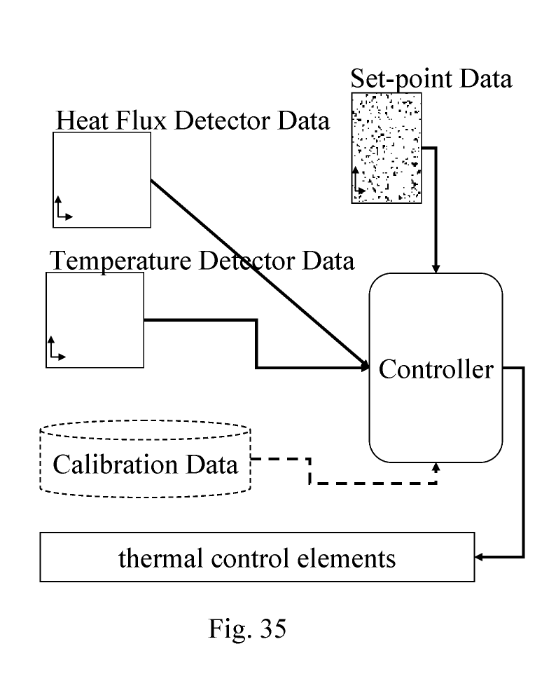

Addressable thermal material design can optionally include a layer of heat flux sensor that monitors heat flux through each segment of the surface. This design is illustrated on FIG. 35. Combination of temperature and heat flux data allows controller to increase precision of thermal control and improve its load and responsiveness. Heat flux detector is an addressable layer that monitors amount of heat passed through each segment of its surface in a unit of time. Its construction can be an independent addressable material or may have shared components with other elements of the addressable thermal material design. Logically it is located on sensory layer of addressable materials model. In some designs it is also possible to position heat flux and temperature detectors on different sides of a body. It is also possible to have design of multiple addressable thermal materials that assembled with multiple layers of heat flux and temperature detectors.

Discrete Functional Layer

This section describes addressable active materials with the functional layer composed of discrete elements. Each of the elements of the functional layer is addressed by continuous one- or two-dimensional address layer. Following example illustrates one of possible types of discrete functional layer.

Micro Channel Based Material

The apparatus/material is designed as a bonding of several layers of polymer materials with channels in some of the layers. Channels are delivering chemical mixes in gas or liquid form to reactor devices integrated in or attached to the material. Each reactor device or group of such devices is individually controlled and may or may not be addressed.

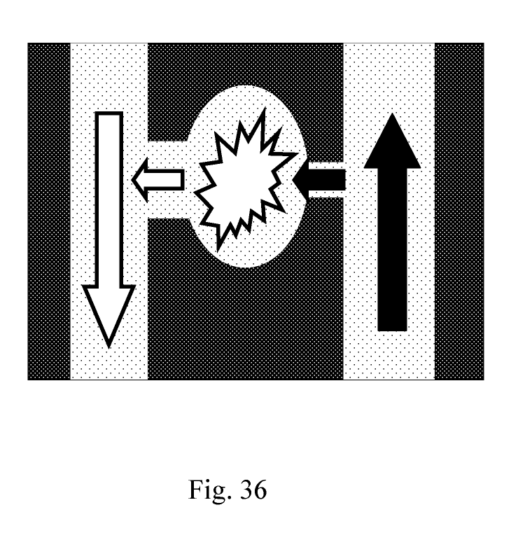

Several possible models for the reactor operation are possible. FIGS. 36 through 41 illustrate these models. It is important to notice that all design models that incorporate valves in their construction do not necessary require chemical reaction to occur in the reactor chamber. It can be just a matter of filling the volume of the reactor with chemical substance (example: supply channel provides colored agent that change transparency of the reactor).

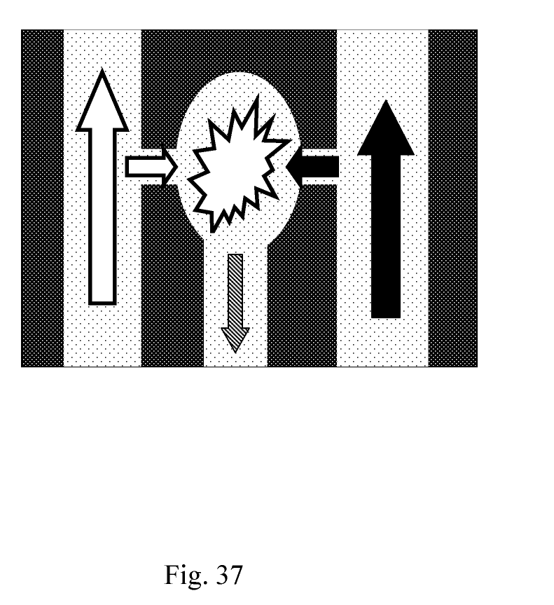

FIG. 36 shows the reactor that receives a mix of chemical reagents through its intake channel, catalyses/initiates chemical reaction and releases products through exhaust channel. Alternative approach is illustrated on FIG. 37. Reactor has two intake channels and one exhaust channel. Individual chemical reagents are mixed inside the reactor. Reaction is initiated either spontaneously or due to features of the reactor itself. Reaction products are released through exhaust channel.

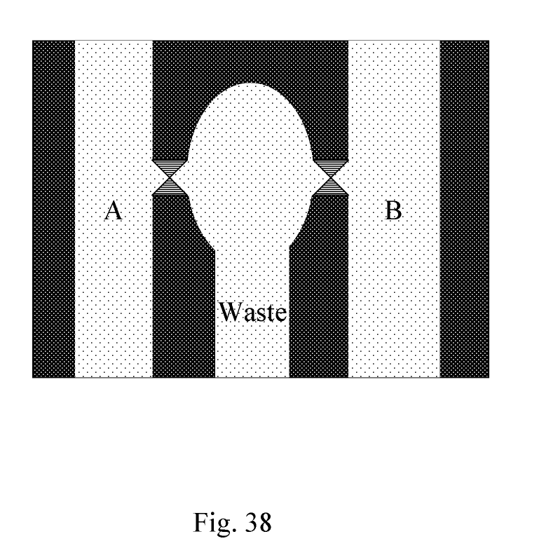

The design shown on FIG. 38 is used when chemical compounds begin reaction on contact with each other. Reactor chamber is isolated from supply channels A and or B by micro valves. In designs with a single valve the cross-section of exhaust channel should significantly exceed the cross-section of open intake channel. Chemical reactions in the reactor chamber occur spontaneously or are catalyzed. The means for catalysis comprise: the walls of the chamber; photo activation, electric/electrochemical actuation; heat/temperature; pressure; acoustic waves; magnetic field; electromagnetic waves.

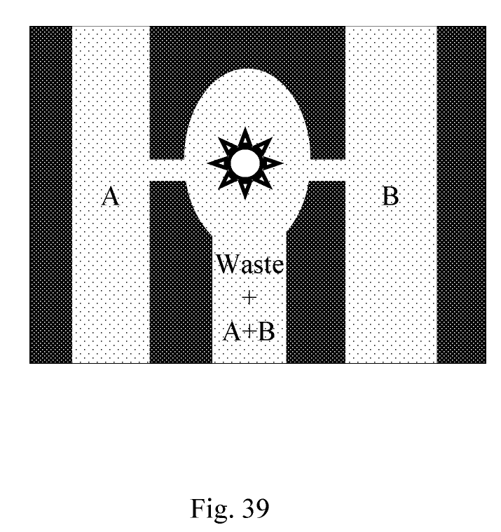

FIG. 39 shows the design that uses bypass principle. All channels are open and chemical reagents A and B freely enters the chamber. No chemical reaction is occurring and formed mix is disposed through the exhaust channel. At desired moment actuating stimulus is turned on which causes initiation of the reaction. When stimulus turns off or when active concentration of the reactive mix becomes too low to sustain the reaction the reaction stops. Important factor in this design is that the cross-section of the intake channels significantly limits the amount of reagents entering the chamber and cross-section of the exhaust channel is sufficient for effective removal of un-reacted mix and reaction products.

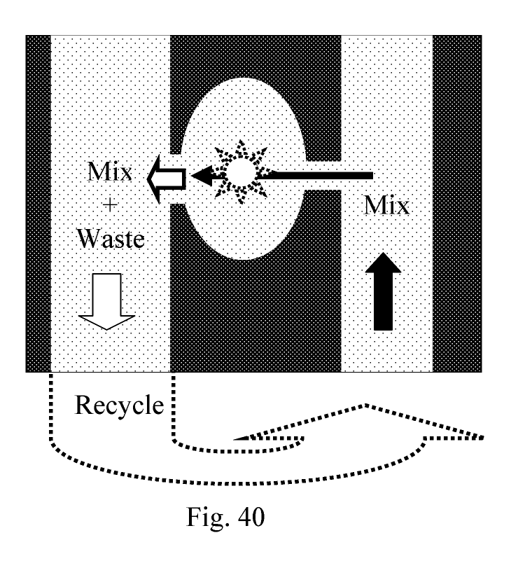

FIG. 40 shows the design that uses by path principle. Chemical mix is freely supplied to the reaction chamber and sequentially flows to the return channel. No chemical reaction occurs. At desired moment actuating stimulus initiates the reaction. When stimulus turns off or when active concentration of the reactive mix becomes too low to sustain the reaction the reaction stops. The products of the reaction are released through the exhaust channel to the return channel. Return channel contains mix of unused chemical reagents and the reaction products. In some scenarios it is easy to separate products from unused reagents (example: Hydrogen/Oxygen mix and water). In such cases return channel directs mix to recycle device that removes products of the reaction and return the reagents to the supply channel.

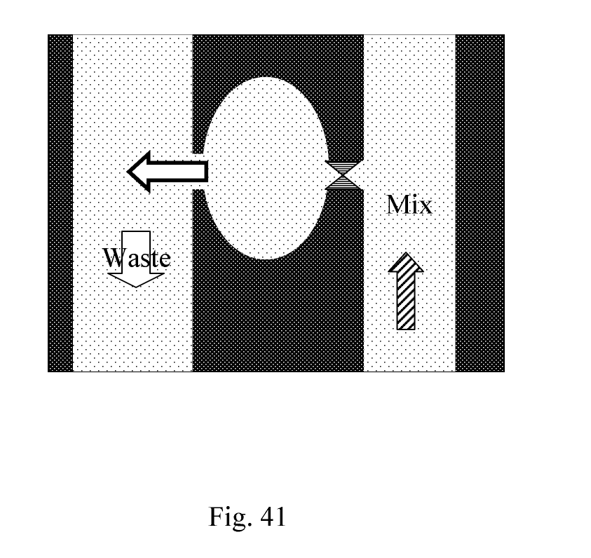

FIG. 41 shows the design with catalytic reactor chamber. The chamber is separated from supply channel by the valve. Opening the valve causes reactive mix to enter the chamber. When required concentration is reached reaction starts on its own due to properties of the chamber. Valve is closed and reaction stops when active concentration of the reactive mix becomes too low to sustain the reaction. Products of the reaction are released through the exhaust channel.

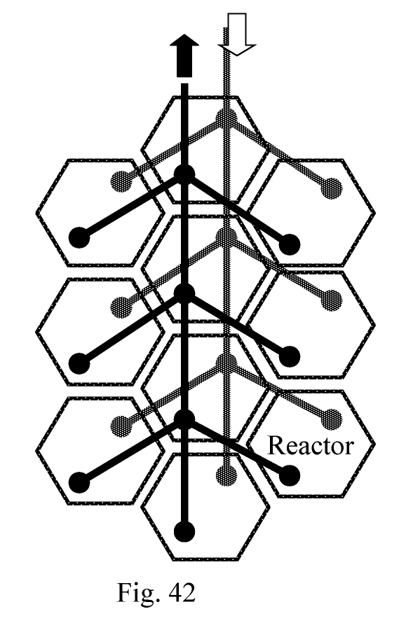

There is large number of possible geometrical layouts for reactors on a surface with different number of supply channels. One example of possible layout is shown on FIG. 42. It has single supply channel per reactor. And reactors are placed in honeycomb pattern.

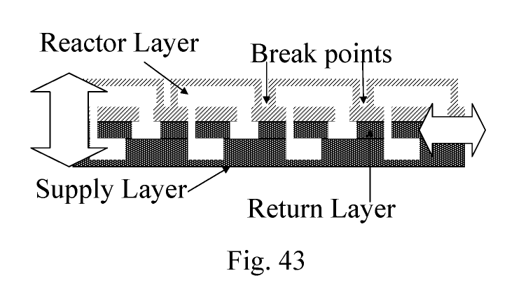

The same is true for layout in layers. Each specific application may require different design. Illustration of one of possible layout is shown on FIG. 43. Both supply and return channels are etched or molded in polymer films. This way they form supply and return layers. Material of these layers may vary with each particular task, as an example it can be Butyl or PTFE. Reactors form its own layer on top. As an example the material of reactors can be Pyrex. Construction of the reactor layer ensures tight binding with supply and return layers. It also allows break points that separate the reactor layer on separate cells in designs that use nonflexible materials. This design provides flexibility and elasticity to the whole assembly.

It is obvious that similar layouts can be created for multiple supply and return channels, as well as combinations of different types of reactors. For briefness of the description these layouts are not given.

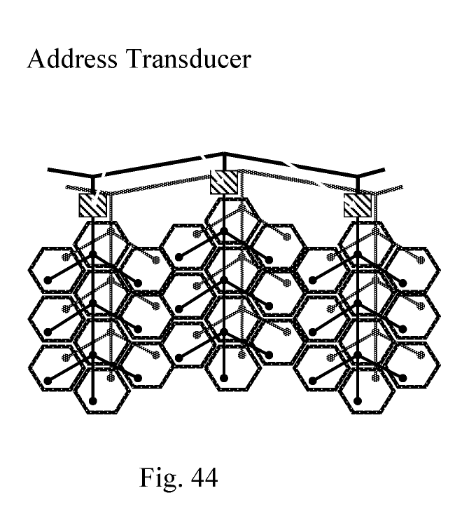

Each cell in described designs of this section may have its own address transducer, or control element such as valve that processes address impulse. Alternatively modular aggregation is possible. Group of cells can form a module which behavior is governed by single control element. Example of this concept is illustrated on FIG. 44, where each group has its own address transducer that allows them to be individually addressed and controlled.

These functional layers can be bound to two-dimensional address layer that utilizes flexible design. Address resolution of this address layer can be selected dynamically to address individual discrete element of the functional layer or group of such elements. As an example piezoelectric, electrostatic, or thermally activated micromechanical valves employed in designs of described reactors can be seamlessly coupled with top surface of address transducer layer to be dynamically controlled. In some cases intensity of electric field inside address impulse can be used as a catalyst in chemical reaction.

This approach provides significant simplification in process of assembly of micromechanical devices since there is no need in performing precise interconnections between array of elements and addressing wires.

Sensor Layer Elements

This section describes discrete sensory elements that can be integrated in continuous addressable material. In some applications they can be the only type of elements composing the functional layer, in other application they can be integrated into existing functional layer and be accessed continuous addressing schema. Following example illustrate some types of sensors that form and arrays connected to the functional layer. Most of these sensors can also be implemented as a continuous functional layer.

Contact Temperature Sensors

These elements are implemented as thermo resistor or thermistor or p-n junction. Their physical location allows direct detection of temperature of the work layer or surface adjacent to it.

Data from these elements are encoded into data layer signal. Example of one of possible encoding schemas is: Current from address transducer causes different voltage on thermistor. This voltage signal is transmitted by shared data layer and decoded into temperature data by controller.

Non-Contact Temperature Sensors

These elements are implemented as IR photoresistor or thermistor or p-n junction located in focus of IR transparent optical device such as microarray of lenses. IR radiation of surface adjacent to the material assembly is registered and converted into temperature data.

Contact Thermo Flux Sensors

Heat flux sensor elements are located on outer surface of the functional layer and register amount of heat passing through the surface in normal direction. Alternatively the temperature sensors that were described in the previous embodiments can be used as a lateral heat flux sensor that monitors lateral heat fluxes in the functional layer or body it is adjacent to.

Light Intensity Sensors

These elements are implemented as photosensitive electronic components, like photoresistor, photodiode etc. They provide data about light intensity distribution along the functional layer.

Spectral Sensors

These elements are similar to light intensity sensors. Their sensitivity to light is distinct in different spectral areas, which allows them to provide data about light spectral composition distribution along the functional layer.

Surface Potential Sensors

These sensors are electronic components or electromechanical devices (MEMS) that are sensitive to intensity of electric field in vicinity of the surface of functional layer. Semiconductor version of these sensors operates on principle of field transistor. Electromechanical versions of these sensors operate on variety of known principles, like chopping amplifier, piezo-resistive sensor, capacitive sensor, etc.

Ionizing Radiation Sensors

These sensors detect level of ionizing radiation like alpha-, beta-, gamma- decay and X-ray radiations. These sensors can be implemented as variety of semiconductor and electronic components. Most of them are sensitive to presence of spontaneously generated carriers of electric current.

Smell Sensors

These sensors are implemented as MEMS devices. They are distributed along the functional layer and provide data about presence of specific chemical compounds in the environment around it.

Electric Current Sensors

These sensors are electronic components that register electric current. They can be implemented as a variety of semiconductor devices, like transistors, Hall Effect sensors and etc. These elements allow receiving data about distribution of environment conductivity along the work surface as well as other characteristics like electrochemical reactions, pH, ion concentration, etc.

Current Sensors

These sensors are electronic components that register current of mobile phase adjacent to the work layer. They can be implemented as a variety of semiconductor devices, MEMS devices, lateral heat flux sensors, and etc. These elements allow receiving data about speed and or mass flow of mobile phase along the functional layer.

Chemical Sensors

These elements are implemented as combination of chemically selective components (like: ligand, DNA, antibody, etc.) and one of the sensor types described above. Alternatively they are implemented as MEMS device that changes its mechanical characteristics under the influence of chemical substances.

1. A method of addressing a continuous range of locations in physical media that employs interference of at least two waves propagating in continuous media, wherein fronts of these waves meet at a location inside the media and said location uniquely identifies a location within said continuous range.

2. A method of claim 1, wherein at least two waves propagate in the same direction with different phase velocities and fronts of these waves meet at a location inside the media and said location uniquely identifies a location within said continuous range.

3. A method of claim 1, wherein said waives propagate through distinct passes, and wherein fronts of these waves interfere in a media that reveal nonlinear properties and said interference uniquely identifies a location within said continuous range.

4. A method of claim 3, wherein there are at least two waves propagating in the same direction with different phase velocities.

5. A method of claim 1, wherein at least two waves have shape of pulses with defined length.

6. A method of claim 2, wherein at least two waves have shape of pulses with defined length.

7. A method of claim 3, wherein at least two waves have shape of pulses with defined length.

8. A method of claim 4, wherein at least two waves have shape of pulses with defined length.

9. A method of claim 5, wherein at least one of the pulses has Gaussian shape.

10. A method of claim 6, wherein at least one of the pulses has Gaussian shape.

11. A method of claim 7, wherein at least one of the pulses has Gaussian shape.

12. A method of claim 8, wherein at least one of the pulses has Gaussian shape.

13. A method of claim 3, wherein properties of said propagation media are nonlinear with respect to amplitude of at least one of said waves.

14. Method of claim 2, wherein properties of said propagation media nonlinear with respect to amplitude of at least one of said waves.

15. An artificially produced structure capable of propagating particular types of waves with low attenuation and utilizing method of claim 1 to dynamically alter a physical property of confined volume of compositing structure.

16. An artificially produced structure of claim 15, wherein said structure has at least one of its base dimensions (height, width, length) 100 times larger than

17. An artificially produced structure of claim 16 that can be bent to form a loop with minimal diameter less than 5 mm.

18. An artificially produced structure of claim 15 that shaped like a fiber and arranged to cover two-dimensional surface using ordered pattern.

19. A structure of claim 18 where in said pattern resembles woven fabric.

20. A structure of claim 18 where in said pattern is parallel lines.

21. A structure of claim 19 where in said pattern is rows and columns, wherein angle between the rows and the columns may be other then Tr/2.

22. An artificially produced structure of claim 15, wherein said structure has at least one of its base dimensions (height, width, length) 100 times smaller other dimension.

23. An artificially produced structure capable of propagating particular types of waves with low attenuation that uses method of claim 1 to query a value of predefined physical property of dynamically selected confined volume of compositing structure.

24. A structure of claim 15 that contains materials with electro-optical properties and said properties are dynamically changeable.

25. (canceled)

26. A structure of claim 15, wherein said composing structure contains array of discrete microstructures.

27. (canceled)
